(19) United States
(12) Patent Application Publication
(10) Pub. No.: US 2020/0048757 A1
(43) Pub. Date: Feb. 13, 2020

(54) ION IMPLANTED HARDMETAL CEMENTED CARBIDE COLD SPRAYED COATINGS

(71) Applicant: UNIVERSITY OF THE WITWATERSAND, JOHANNESBURG, Johannesburg (ZA)

(72) Inventors: Peerawatt Nunthavarawong, Johannesburg (ZA); Natasha Sacks, Fairland (ZA)

(21) Appl. No.: 16/492,641

(22) PCT Filed: Mar. 15, 2017
(86) PCT No.: PCT/IB2017/051483

§ 371 Date: Sep. 10, 2019

(51) Int. Cl. C23C 14/06; C23C 14/48

(52) U.S. Cl. CPC C23C 14/0635; C23C 14/48

(57) ABSTRACT

The present invention provides for an ion implanted cold sprayed hardmetal cemented carbide coating and a method to prepare the coating. The coating comprises hardmetal carbide and a binder metal M selected from nickel, cobalt, copper, iron, and alloys thereof. The coating is implanted with ions selected from Nb⁺, Mo⁺, W⁺, Ta⁺, and Ru⁺ ions.

### INTRODUCTION

This invention relates to an ion implanted hardmetal cemented carbide coating and to a method of preparing the ion implanted coating. In particular, but not exclusively, the invention relates to a WC based ion implanted coating and a method to prepare the coating.

### BACKGROUND

Low pressure cold gas dynamic spraying has been used to produce a range of versatile coatings for various applications over the past few decades.

Tungsten carbide-based coatings, for example, produced using this technique do not have the tendency to display undesirable coating properties such as tensile residual stress, thermal oxidation, phase transformations, and grain growth during deposition.

However, the resultant coatings generally experience a low retention of the WC particles, as well as erosion of the substrate and erosion of previously deposited layers by hard WC particles on impact during the deposition process. These factors may lead to increased crack formation and higher porosity levels which result in a decrease in coating hardness, strength and wear properties.

There is therefore a need for cold sprayed hardmetal cemented carbide based coatings with enhanced mechanical and wear properties, thereby to ensure a desirable operational lifetime of the coatings in use.

The inventors of the present invention have found that ion implantation of hardmetal cemented carbide cold spray coatings, successfully produced cermet coatings with a significant and unexpected improvement in both the mechanical and wear properties.

### SUMMARY OF THE INVENTION

According to a first aspect of the present invention there is provided an ion implanted cold sprayed hardmetal cemented carbide coating, the coating comprising a hardmetal carbide and a binder metal M selected from the group consisting of nickel, cobalt, copper, iron, and alloys thereof, wherein the coating is implanted with ions selected from the group consisting of Nb⁺, Mo⁺, W⁺, Ta⁺, and Ru⁺.

In one embodiment, the hardmetal cemented carbide is selected from the group consisting of WC-M, TiC-M, TaC-M, ZrC-M, Cr₂C₃-M, NbC-M, VC-M, and MoC-M, or mixtures thereof.

In one embodiment, the binder metal M is present at a concentration of about 2% to about 20% by weight of the total coating.

In a preferred embodiment, the binder metal M is present at a concentration of about 3% to about 15% by weight of the total coating.

In a particularly preferred embodiment, the binder metal M is present at a concentration of about 5% to about 10% by weight of the total coating.

Preferably, the coating is implanted with Nb⁺ ions.

Preferably, the binder metal M is selected from the group consisting of nickel, cobalt, iron, and alloys thereof.

More preferably, the binder metal M is selected from nickel and alloys thereof.

In one embodiment, the ions are implanted at a dosage in the range of about 1×10¹⁶ to about 1×10¹⁷ ions cm⁻².

In a preferred embodiment, the ions are implanted at a dosage of about 2×10¹⁶, about 5×10¹⁶, about 8×10¹⁶, or about 1×10¹⁷ ions cm⁻².

According to a second aspect of the present invention there is provided a method of forming an ion implanted cold sprayed hardmetal cemented carbide coating, the method comprising the steps of:
(a) cold spraying a hardmetal cemented carbide coating onto a substrate to be coated, and
(b) implanting ions selected from the group consisting of Nb⁺, Mo⁺, W⁺, Ta⁺, and Ru⁺ with an ion implanter at an acceleration voltage of about 40 keV to about 170 keV,

wherein the coating comprises a hardmetal carbide and a binder metal M selected from the group consisting of nickel, cobalt, copper, iron, and alloys thereof.

In one embodiment, the hardmetal cemented carbide is selected from the group consisting of WC-M, TiC-M, TaC-M, ZrC-M, Cr2C3-M, NbC-M, VC-M, and MoC-M, or mixtures thereof.

In one embodiment of the method, the binder metal M is present at a concentration of about 2% to about 20% by weight of the total coating.

In a preferred embodiment of the method, the binder metal M is present at a concentration of about 3% to about 15% by weight of the total coating.

In a particularly preferred embodiment of the method, the binder metal M is present at a concentration of about 5% to about 10% by weight of the total coating.

Preferably, the coating is implanted with Nb⁺ ions.

In one embodiment of the method, the binder metal M is selected from the group consisting of nickel, cobalt, iron, and alloys thereof.

In a preferred embodiment of the method, the binder metal M is selected from nickel and alloys thereof.

Preferably, the ions are implanted at a dosage in the range of about 1×10¹⁶ to about 1×10¹⁷ ions cm⁻².

Even more preferably, the ions are implanted at a dosage of about 2×10¹⁶, about 5×10¹⁶, about 8×10¹⁶, or about 1×10¹⁷ ions cm⁻².

### BRIEF DESCRIPTION OF THE DRAWINGS

The invention will now be described in more detail with reference to the following non-limiting embodiments and figures in which:

FIG. 1 shows AFM images of (a) WCNI, (b) NB-216, (c) NB-516, (d) NB-816, and (e) AFM depth profiling;

FIG. 2 shows a graphical representation of the relation of the mean radius of asperities parameter and reciprocal parameter of the comprehensive roughness fraction;

FIG. 3 shows a graphical representation of Vickers-micro hardness values of NB-x16 and WCNI substrates, deposited on stainless steel.

FIG. 4 shows a graphical representation of plasticity index values of NB-x16 and WCNI substrates;

FIG. 5 shows a graphical representation of friction response as a function of sliding distance for the NB-x16 and WCNI substrates;

FIG. 6 shows FESEM images of the wear tracks on WCNI (a and e), NB-216 (b), NB-516 (c), and NB-816 (d and h), with elemental mapping of WCNI and NB-816 worn tracks for Fe (f and i) and O (g and j) respectively;

FIG. 7 shows wear scar images with EDS analyses of the 100Cr6 steel ball sliding against WCNI (a), NB-216 (b), NB-516 (c), and NB-816 (d);

FIG. 8 shows FESEM images (a and f) of wear debris from WCNI/ball counterfaces, with elemental mapping of wear debris showing maps of Fe (b and g), O (c and h), Ni (d and i), and W (e and j);

FIG. 9 shows FESEM images (a and g) of wear debris from NB-816/ball counterfaces, with elemental mapping of wear debris showing maps of Fe (b and h), O (c and i), Ni (d and j), W (e and k), and Nb (f and l);

FIG. 10 shows shear stress distribution plots of WCNI (a), NB-216 (b), NB-516 (c), and NB-816 (d);

FIG. 11 shows von Mises stress distribution plots of WCNI (a), NB-216 (b), NB-516 (c), and NB-816 (d); and

FIG. 12 shows a graphical representation of local maximum von Mises yield stress beneath the sliding contacts of WCNI (a), NB-216 (b), NB-516 (c), and NB-816 (d).

### DETAILED DESCRIPTION OF PREFERRED EMBODIMENTS

The present invention will now be described more fully hereinafter with reference to the accompanying figures, in which some of the non-limiting embodiments of the invention are shown.

The invention as described hereinafter should not be construed to be limited to the specific embodiments disclosed, with slight modifications and other embodiments intended to be included within the scope of the invention.

Although specific terms are employed herein, they are used in a generic and descriptive sense only and not for purposes of limitation.

As used herein, throughout this specification and in the claims which follow, the singular forms “a”, “an” and “the” include the plural form, unless the context clearly indicates otherwise.

The terminology and phraseology used herein is for the purpose of description and should not be regarded as limiting. The use of the terms “comprising”, “containing”, “having”, “including”, and variations thereof used herein, are meant to encompass the items listed thereafter, and equivalents thereof as well as additional items.

The present invention provides for an ion implanted cold sprayed hardmetal cemented carbide coating, for example a tungsten carbide based WC-M coating. The coating is implanted with ions selected from the group consisting of Nb⁺, Mo⁺, W⁺, Ta⁺, and Ru⁺, and the binder metal M may be selected from the group consisting of nickel, cobalt, copper, iron, and alloys thereof.

The hardmetal carbide is selected from the group consisting of WC, TiC, TaC, ZrC, Cr₂C₃, NbC, VC, MoC, and mixtures thereof. In a preferred embodiment of the invention the coating is a WC based hardmetal carbide composition.

The binder metal M may be present in the tungsten carbide based coating at a concentration of about 2% to about 20% by weight of the total coating, preferably the binder metal M is present at a concentration of about 3% to about 15% by weight of the total coating, more preferably the binder metal M is present at a concentration of about 5% to about 10% by weight of the total coating, most preferably the binder is present at a concentration of about 5%, 7.5%, or 10% by weight of the total tungsten carbide based WC-M coating.

The binder metal M may be selected from the group consisting of nickel, cobalt, copper, iron, and alloys thereof, preferably the binder metal M is nickel, cobalt, iron, and alloys thereof, more preferably the binder metal M is nickel, or cobalt, and alloys thereof, most preferably the binder metal M is nickel and alloys thereof.

The ions may be implanted into the ion implanted cold sprayed hardmetal cemented carbide coating at a dosage in the range of about 1×10¹⁶ to about 1×10¹⁷, preferably the ions are implanted at a dosage of about 2×10¹⁶, about 5×10¹⁶, about 8×10¹⁶, or about 1×10¹⁷.

The invention will be described in more detail below with reference to a number of non-limiting experimental embodiments and characterisation data.

### EXAMPLE 1

### Preparation of a Cold Sprayed Nb Implanted WC-5 wt % Ni Coatings

WC-5 wt % Ni cermet coatings (referred to as WCNI) were deposited onto 3CR12 stainless steel plates (20 mm×20 mm×3 mm) using a low pressure cold gas dynamic spray machine (Centerline SST Series P, Canada). Spray parameters were optimized according to the disclosure contained in P. Nunthavarawong et al., Effect of powder feed rate on the mechanical properties of WC-5 wt % Ni coatings deposited using low pressure cold spray, Int. J. Refract. Met. Hard Mater. 61 (2016) 230-237, which is incorporated herein in its entirety by reference.

Coating samples were ground using standard metallographic procedures and polished to a 1 μm surface finish, and then ultrasonically cleaned prior to the ion implantation process. The selected Nb ion sputtering target (Niobium (99.9%, Goodfellow, UK) was implanted into the cermet coatings in varying dosages of 2×10¹⁶, 5×10¹⁶, and 8×10¹⁶ ions cm⁻² at an acceleration voltage of 60 keV (200-20A2F ion implanter, iThemba LABS, South Africa). These ion implanted coatings are referred to as NB-216, NB-516, and NB-816 elsewhere in the specification.

Surface and Microstructural Characterization

In order to investigate the surface topography, the specimens, both implanted and un-implanted samples were characterized using an atomic force microscope (AFM, Dimension 3100, Digital Instruments Inc., USA) in tapping mode, coupled with Nano Scope Analysis Version 1.30 (Bruker Corporation, USA) software to measure the surface roughness.

A silicon probe was used at a scan rate of 1.0 Hz (tip radius=8 nm, resonance frequency=75 kHz, spring constant=2.8 Nm⁻¹, Young's modulus=169 GPa; supplier specifications Digital Instruments Inc.).

Five different surface roughness parameters, according to ISO 4287 (Geometrical Product Specifications (GPS)—Surface Texture: Profile Method—Terms, Definitions and Surface Texture Parameters, ISO Stand. (1997) 1-25), were selected to evaluate both the surface topography after implantation as well as the worn surfaces. The roughness data was then applied to McCool's equation (I. J. McCool, Relating profile instrument measurements to the functional performance of rough surfaces, J. Tribol. 109 (1987) 264-270) to determine the mean radius of the asperities (ρ=3/8(π/Rₖᵤ)^{1/2}). Then, ρ was used to determine the comprehensive roughness fraction (Δ), and in the current research the reciprocal parameter of Δ, as shown in Equation 1, where Rₘₐₓ is the maximum roughness depth was employed.

1/Δ=(Rₘₐₓ/ρ)⁻¹ (1)

Micro-Vickers hardness tests (Future tech FM-700, Japan) were done on the planar surfaces of samples using a 0.49 N load (HV_{0.05}) with a 10 s dwell time according to ASTM C1327 (Standard Test Method for Vickers Indentation Hardness of Advanced Ceramics, ASTM Stand. (2015) 1-10). The plasticity index (ψ) of the samples was determined using Equation 2 where E*, H_{V}, and R_{q} are the Hertz elastic modulus between the samples and the silicon AFM probe, the Vickers hardness, and the root mean square deviation of the assessed roughness profile.

ψ=(E*/H_{V})(R_{q}/ρ)^{1/2} (2)

The dry sliding wear tests were performed using a ball-on-disk tribometer (Standard Tribometer Series, Anton Paar TriTec, Switzerland) equipped with TriboX software, where the coatings were the disk, while 6 mm 100Cr6 stainless steel balls were used as the ball counterface.

Prior to the wear tests, the coating specimens and ball counterfaces were cleaned ultrasonically with acetone for 10 minutes to remove any possible contaminants on the surfaces. Dry sliding conditions were employed using a normal force (W) of 1 N, sliding velocity (v) of 0.05 ms⁻¹, sliding duration of 10⁴ cycles (L=126.23 m), and a sampling rate frequency of 50 Hz. In order to determine the wear rates, a stereo microscope (Nikon SMZ745T, Japan) and MS Elements imaging software v4.0, was used to measure the width (w) and mean radius (R) of the wear tracks. These values were then used to calculate the wear volume of the sample (Vₛ) using Equation 3, where r is the original radius of the ball. The specific wear rate of the samples (W_{S}) and the wear coefficient (Kₛ) were determined using Equations 4 and 5 respectively.

Vₛ=(π/6)(w³/r)R (3)

Wₛ=Vₛ/WL (4)

Kₛ=WₛH_{V} (5)

The wear scar diameters on the minor axis (A) and major axis (B) of the ball counterface were measured on FESEM images and then used to calculate the volume loss of the ball counterface (v_{c}), using Equation 6, where d is the original diameter of the ball.

V_{c}=πA³B/32d (6)

The specific wear rate of the ball counterface (W_{c}) was computed using Equation 7.

W_{c}=V_{c}/WL (7)

A field emission scanning electron microscope (FESEM, Carl Zeiss Sigma, Germany) was used to identify the wear mechanisms of the coatings and balls in secondary electron (SE) and back scattered imaging mode (BSE). Elemental composition analyses were done according to ASTM E1508 (Standard Guide for Quantitative Analysis by Energy-Dispersive Spectroscopy, ASTM Stand. (2012) 1-9) using the energy dispersive X-ray spectrometer (EDS, INCA x-act detector, Oxford Instruments, UK) attached to the FESEM.

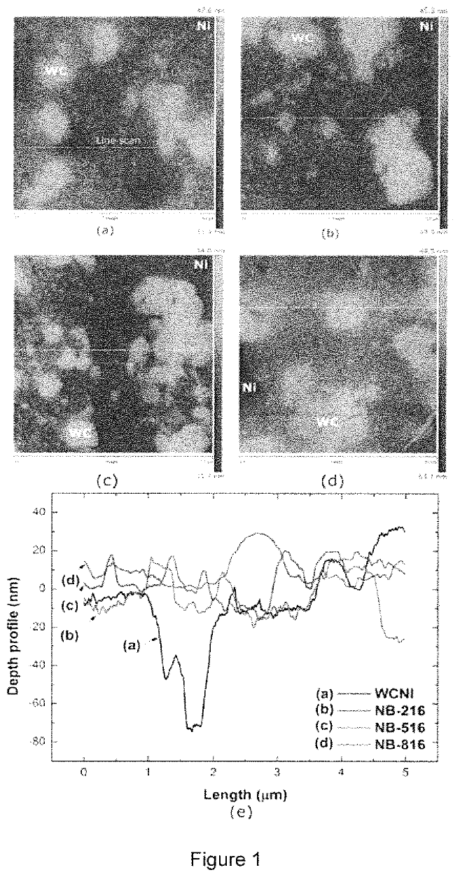

Semi-analytical sliding contact analysis was performed in order to determine the stress distribution beneath the sliding surfaces in contact during the wear tests, i.e. the normalized shear (τ_{zx}/Pₘₐₓ), and the normalized von Mises stress (σ_{VM}/Pₘₐₓ), using the model described in Hamilton, 1983. (G. M. Hamilton, Explicit equations for the stresses beneath a sliding spherical contact, Proc. Inst. Mech. Eng. 197, (1983) 53-59). The coordinate of each stress component is indicated in FIG. 1, and the relevant parameters used in the analyses are listed in Table 3. The local maximum yield stress at the top surface (Ysₘₐₓ) was evaluated using Equation 8, where ϕₛ is the maximum value of the normalized von Mises stress at the top surface and Pₘₐₓ is the maximum Hertzian pressure.

Ysₘₐₓ=ϕₛ Pₘₐₓ (8)

### EXPERIMENT 2

### Surface Characterization and Analyses of Nb Implanted WC-5 wt. % Ni Coatings

As can be seen from FIG. 1, the AFM micrographs on the planar surfaces of the coatings, clearly display the WC particles (bright phase) embedded within the Ni matrix (colour/darker phase) for all samples.

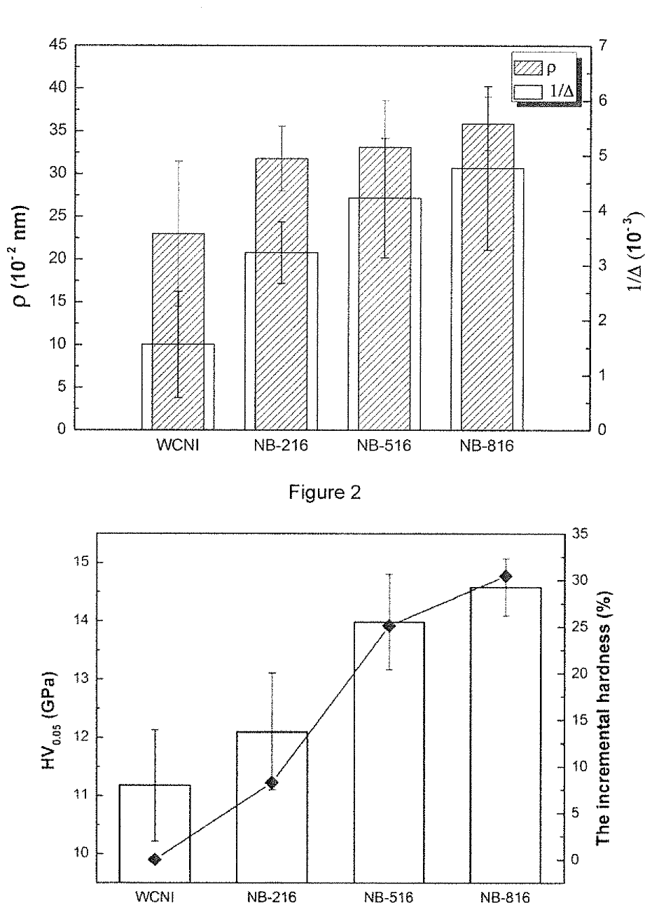

On the AFM surface depth profiles of the samples, shown in FIG. 2e, the deep valleys on the surface of the WCNI coating were due to carbide removal during metallographic polishing, while some of the shallow valleys are likely due to removal of the ductile Ni binder also during polishing. This removal is attributed to the small carbide grain size and the small Ni binder mean free path. The depth profiles of the ion implanted coatings showed, not only smoother surfaces, but also more positive (higher) profiles compared to the un-implanted coating. This is especially true for the highest ion dosage of Nb used for sample NB-816; these profiles show that ion implantation can assist in building up the coating surface in order to attain a smoother surface finish.

This is confirmed by comparing the Rq and Ra roughness parameters shown in Table 1 below, wherein the roughness values of all ion implanted specimens is lower than those of the un-implanted WCNI materials. For example, the Rq of the WCNI materials was 16.57 nm, while for NB-216, NB-516, and NB-816, Rq had values of 12.04, 11.49, and 10.22 nm respectively. These findings are attributed to the viscous relaxation produced by the ion beam at high dosages, thereby achieving less rough surfaces.

TABLE 1
The surface roughness parameters of samples and ball counterfaces

| | Unworn surface | | | | |
|---|---|---|---|---|---|
| Parameter (nm) | Ball | WCNI | NB-216 | NB-516 | NB-816 |
| Rq | 16.82 ± 7.59 | 16.57 ± 13.63 | 12.04 ± 2.53 | 11.49 ± 1.36 | 10.22 ± 1.46 |
| Ra | 11.65 ± 5.19 | 14.15 ± 8.85 | 9.84 ± 1.99 | 8.87 ± 1.51 | 7.75 ± 0.87 |
| Rmax | 115.45 ± 31.99 | 164.38 ± 56.98 | 99.84 ± 12.20 | 81.85 ± 16.61 | 82.48 ± 26.95 |
| Rz | 7.90 ± 2.71 | 7.95 ± 2.71 | 6.70 ± 1.09 | 11.10 ± 6.23 | 7.37 ± 1.45 |
| Rku | 10.11 ± 6.07 | 12.49 ± 8.88 | 4.55 ± 1.08 | 4.29 ± 1.20 | 3.50 ± 0.61 |

| | Worn ball surface | | | |
|---|---|---|---|---|
| Parameter (nm) | WCNI | NB-216 | NB-516 | NB-816 |
| Rq | 17.73 ± 13.94 | 11.55 ± 6.73 | 7.35 ± 4.78 | 8.73 ± 5.32 |
| Ra | 11.77 ± 8.42 | 8.48 ± 4.72 | 5.82 ± 3.85 | 6.16 ± 3.88 |
| Rmax | 163.55 ± 120.03 | 142.34 ± 26.12 | 81.66 ± 33.53 | 65.74 ± 12.02 |
| Rz | 22.37 ± 25.48 | 3.59 ± 2.56 | 6.35 ± 8.10 | 5.49 ± 3.25 |
| Rku | 8.59 ± 10.32 | 4.36 ± 0.83 | 3.62 ± 0.56 | 4.53 ± 1.97 |

| | Worn track surface | | | |
|---|---|---|---|---|
| Parameter (nm) | WCNI | NB-216 | NB-516 | NB-816 |
| Rq | 17.39 ± 8.40 | 132.31 ± 65.40 | 52.25 ± 23.84 | 31.80 ± 10.78 |
| Ra | 13.95 ± 7.21 | 77.39 ± 24.60 | 42.50 ± 20.78 | 25.59 ± 8.92 |
| Rmax | 241.66 ± 31.56 | 364.00 ± 50.85 | 196.88 ± 36.72 | 157.21 ± 42.57 |
| Rz | 10.70 ± 7.59 | 134.63 ± 70.52 | 101.33 ± 80.64 | 53.46 ± 23.79 |
| Rku | 3.21 ± 1.07 | 4.48 ± 2.33 | 3.19 ± 0.45 | 2.99 ± 0.47 |

The improvement in surface roughness can further be seen from FIG. 2, which compares the mean radius of asperities (ρ) and the reciprocal value of the comprehensive roughness fraction (1/Δ), which increases as the ion dosage increases.

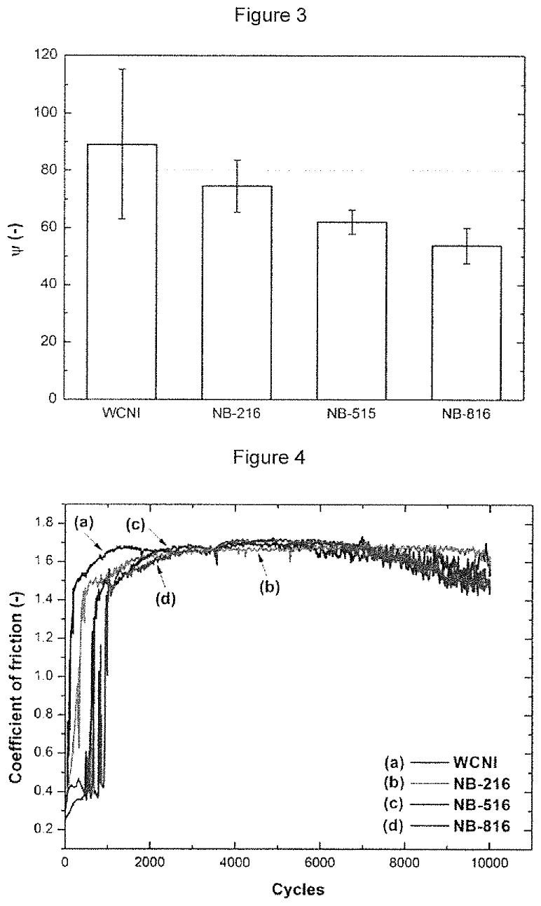

FIG. 3 shows the improvement in surface hardness due to ion implantation with the NB-816 materials showing the highest average hardness of 14.58±0.49 GPa which translates into an increase of 30.45% compared to the un-implanted WCNI coating. This increase is attributed to the amorphous Nb layer which increases as a function of ion dosage.

The correlation between surface hardness and surface properties is represented by the plasticity parameter, as shown in FIG. 4, which shows that, as the ion dosage increases, the plasticity indices (ψ) decrease.

### EXPERIMENT 3

### Friction and Wear Response of Nb Implanted WC-5 wt. % Ni Coatings

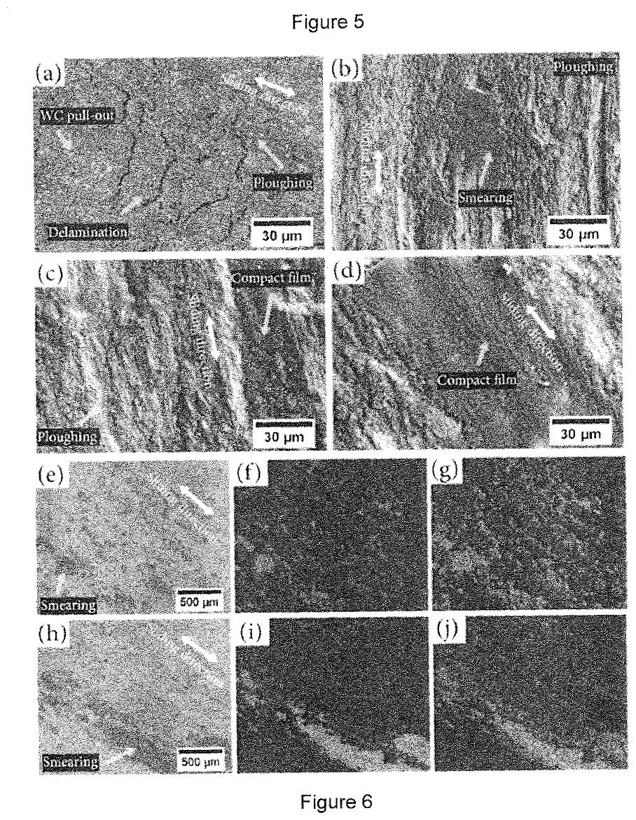

FIG. 5 shows the friction response of the samples as a function of the number of wear cycles. The evolution of friction of all the materials showed two distinct friction regions, namely an initial running-in friction phase followed by a steady-state friction region.

For the WCNI materials, the friction coefficient increased sharply within the first few cycles of sliding and reached the steady-state friction region quickly, with an average friction coefficient of 1.675. The three ion implanted samples reached the steady state friction regions after longer time periods, with the number of cycles increasing as the ion dosage increased. The mean values of the steady state friction coefficients for NB-216, NB-516, and NB-816 were 1.661, 1.694 and 1.707 respectively. The measured volume loss and wear parameters for each coating are listed in Table 2. The wear rate did not align with the corresponding friction values, in that high friction values did not give rise to high wear rates. The wear rates and wear coefficients decreased as the ion dosage increased, with the lowest wear rate being achieved by the cermet coating implanted with the highest Nb ion dosage, where a more than 50% decrease was observed. These results imply that ion implantation can be considered as a process by which the wear properties of cold spray coatings may be greatly enhanced.

TABLE 2
The wear properties of Nb ion implanted
coatings and un-implanted WC-5 wt % Ni

| | Material | | | |
|---|---|---|---|---|
| Factor | WCNI | NB-216 | NB-516 | NB-816 |
| Wear track radius, R (10⁻³ m) | 6.90 | 6.88 | 6.59 | 6.31 |
| Wear track width, w (10⁻³ m) | 2.24 | 2.20 | 1.71 | 1.60 |
| Wear volume of sample, V_{S} | 13.6 | 12.9 | 5.74 | 4.51 |
| (10⁻⁹ m³) | | | | |
| Wear rate of sample, W_{S} | 108 | 102 | 45.4 | 35.7 |
| (10⁻¹² m² N⁻¹) | | | | |
| Wear coefficient, K_{S} (—) | 1.20 | 1.23 | 0.64 | 0.52 |
| Wear volume of counterface, V_{C} | 2.18 | 2.21 | 2.14 | 1.90 |
| (10⁻¹¹ m³) | | | | |
| Wear rate of counterface, W_{C} | 1.73 | 1.75 | 1.69 | 1.50 |
| (10⁻¹³ m² N⁻¹) | | | | |

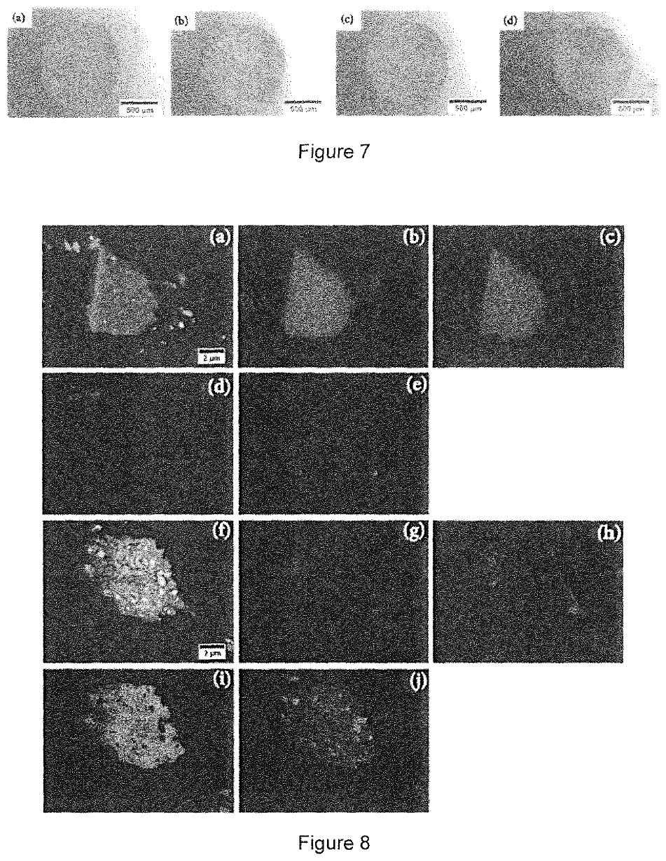

The worn surfaces of the coatings and steel balls in FIGS. 6 and 7 respectively, show the different levels of surface damage experienced during the wear tests. FIG. 6 shows FESEM images of the wear tracks on (a and e) WCNI (b) NB-216 (c) NB-516 (d and h) NB-816, with elemental mapping of WCNI and NB-816 worn tracks (f and i) Fe and (g and j) O respectively. FIG. 7 shows wear scar images with EDS analyses of the 100Cr6 steel ball sliding against (a) WCNI (b) NB-216 (c) NB-516 and (d) NB-816.

The wear modes on the wear tracks of the coatings include delamination, scratching, ploughing, smearing and cracking. For the WCNI coating this mechanism is attributed to lamellar wear formation which increases the wear rate under even the lightest of applied loads, leading to increased material loss and adhered wear debris. Some scratches and ploughing took place parallel to the sliding direction; initially caused by the initial deformation of the asperities on the contacting surfaces. Subsequent scratching and ploughing are then caused through an abrasive wear mechanism by fragmented WC grains and wear debris during sliding, thus changing the wear system into a three body abrasion wear mechanism which accelerates the wear rate.

The ion implanted coatings had higher levels of smearing on the worn tracks than the un-implanted WCNI coating. Smearing is also likely to reduce the friction of these materials, which may account for the lower friction coefficients observed. There also appears to be a compacted tribo-film on the ion implanted worn surfaces, which may be attributed to the initial plastic deformation and shear slip of the ductile Ni phase, as well as initial cracking of the amorphous Nb⁺ layer and WC particles, thereby resulting in a delamination mechanism. This tribo-film is also inclined to decrease the wear rate of the ion implanted coatings, as it will reduce the shear force between the contacting surfaces. In FIGS. 6e-g and FIGS. 6f-j the oxidative wear mechanism was confirmed on the worn tracks, as represented by the iron and oxygen maps, indicating that the steel balls had oxidized and transferred onto the coating surfaces during wear.

FIG. 7 represents typical wear scars on the 100Cr6 steel balls. In general similar features were observed on the balls used for all the coatings with some grooving indicating wear debris abrasion. The leading edge of the balls is also noted by the pile-up of debris along one section of the ball circumference.

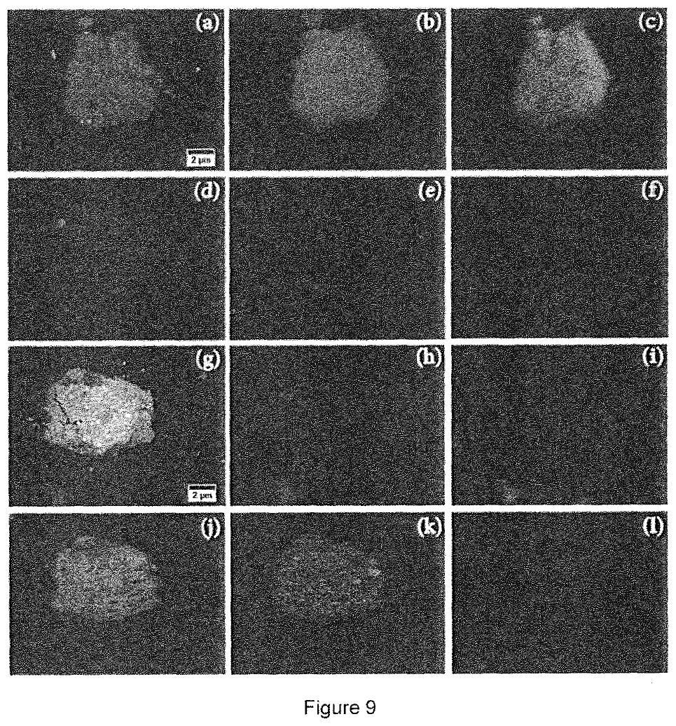

FIGS. 8 and 9 are elemental mappings of wear debris particles from worn surfaces of WCNI and NB-816 respectively, collected after a sliding distance of 10⁴ cycles under an applied load of 1N. FIG. 8 (a and f) show FESEM images of wear debris from WCNI/ball counterfaces. FIG. 8 further shows elemental mapping of wear debris showing maps of Fe (b and g), O (c and h), Ni (d and i), and W (e and j). Similarly, FIG. 9 (a and g) show FESEM images of wear debris from NB-816/ball counterfaces, while elemental mapping of wear debris is showing maps of Fe (b and h), O (c and i), Ni (d and j), W (e and k), and Nb (f and l). The wear debris was used to investigate and confirm the wear mechanisms observed on the worn tracks of the coatings and balls. Oxygen and iron were the predominant elements found on the wear debris thereby supporting the oxidative wear mechanism. Small traces of Ni, W and Nb were also found on the debris, demonstrating the material transfer mechanism between the balls and coatings.

### EXPERIMENT 4

### Sliding Contact Stress of Nb Implanted WC-5 wt. % Ni Coatings

The stress beneath the sliding contacting surfaces which contributes to the deformation of hardmetal coatings may be described by a Hertzian elastic stress distribution.

In the current invention the Hertzian stress parameters for the coatings and steel balls are listed in Table 3.

TABLE 3
The parameters for sliding contact analysts

| Parameter | Magnitude |
|---|---|
| Applied force , W (N) | 1 |
| Friction coefficient of WCNI, NB-216, NB-516, | 1.675, 1.661, |
| NB-816, μ (—) | 1.694, 1.707 |
| Tangential force, F_{X} (N) | μW |
| Ball radius, r (10³ μm) | 2.99 |
| Young's modulus of ball, WCNI, NB-x16, E (GPa) | 210, 82 [5], 105 |
| Poisson's ratio of ball, WCNI, N8-x16, ν (—) | 0.3, 0.22, 0.4 |
| Maximum Hertzian pressure of ball/WCNI, | 440, 522 |
| ball/NB-x16, Pₘₐₓ (MPa) | |
| Hertzian contact radius of ball/WCNI, ball/NB-x16, | 32.94, 30.24 |
| a (μm) | |

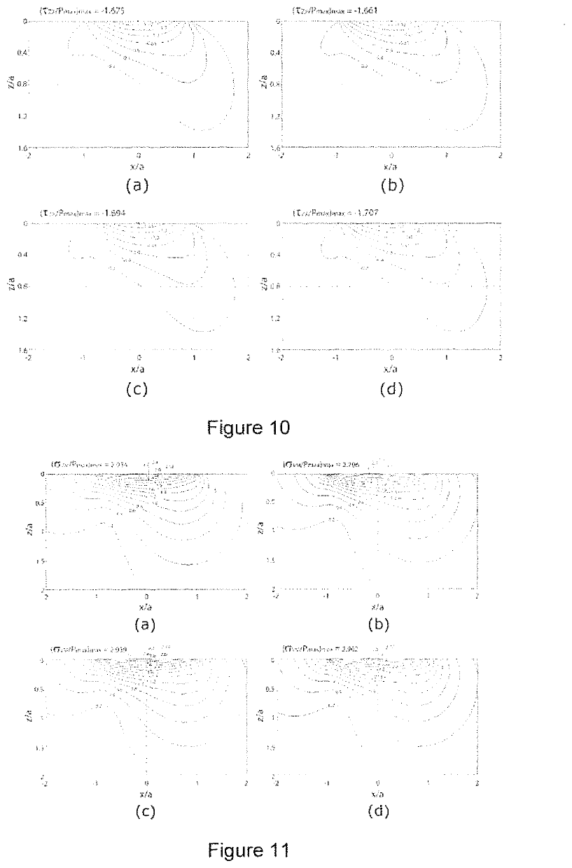

The shear stress and von Mises stress distributions represented on the xz plane (y plane=0, at the surface) as functions of depth (z/a) and width (x/a), computed by different friction coefficients for each material, were plotted as stress contour maps shown in FIGS. 10 and 11. It is well-known that the position and magnitude of the maximum shear stress experienced at or below a sliding surface depends to a great extent on the magnitude of the friction coefficient; this is attributed to the maximum shear stress and huge shear strain appearing on the contacting surfaces.

FIG. 10 illustrates the shear stress distributions (τ_{zx}) and indicates that the normalized shear stress (τ_{zx}/Pₘₐₓ) at the maximum points had values of −1.675, −1.661, −1.694, and −1.707 for the WCNI and NB-x16 ion implanted surfaces respectively, while the negative maximum shear stress had magnitudes of 737, 868, 884, and 891 MPa respectively. Thus the NB-816 coating which had the highest Nb ion dosage had the highest shear resistance, which contributed to the achievement of the lowest wear rate.

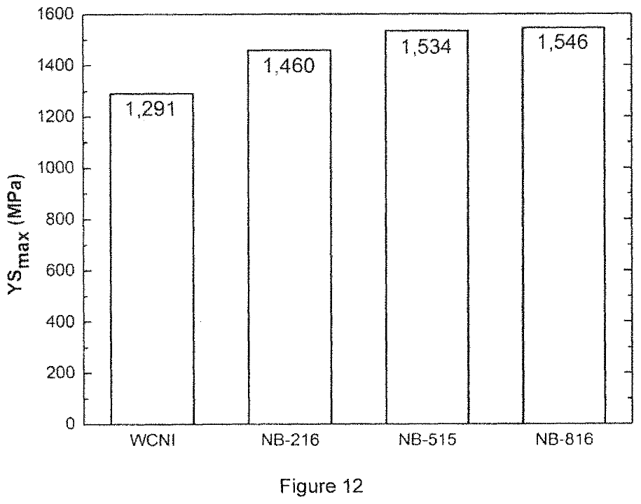

In order to assess the location and magnitude of the onset of plasticity or the initial yield point, the von Mises stress distributions (σ_{VM}) were constructed as shown in FIGS. 11a-d. The maximum value of the normalized von Mises stress (σ_{VM}/Pₘₐₓ)ₘₐₓ for each material was 2.934, 2.796, 2.939 and 2.962 respectively. The surface deformation of the coatings can then be considered as the yield criterion for the von Mises stress, with the local maximum yield stress at the top surface (Ysₘₐₓ) being evaluated from the maximum value of the normalized von Mises stress at the top surface (ϕs), and the maximum Hertzian contact pressure (Pₘₐₓ) which is shown in FIG. 12. The local maximum yield stress at the top surface (Ysₘₐₓ) for each material had magnitudes of 1291, 1460, 1534 and 1546 MPa, and it is noted that the local maximum yield stress at the top surface (Ysₘₐₓ) increases as the ion dosages increase. Thus, these Ysₘₐₓ values support the trend observed in the measured wear rates for the coatings.

Ion implantation of WC-M cold spray coatings, in particular Nb ion implantation of WC-Ni could spray coatings, successfully produced cermet coatings with a significant improvement in both the mechanical and wear properties. Nb ion dosages of 2×10¹⁶, about 5×10¹⁶, about 8×10¹⁶, or about 1×10¹⁷ ions cm⁻² produced coatings with improved coating surface properties. These dosages were also found to be effective in achieving an increased hardness, lowered plasticity index, lowered wear rate, lowered wear coefficient, increased shear strength, and improved local maximum yield strength.

### EXAMPLE 5

### Preparation of a Cold Sprayed Nb Implanted WC-5 wt % Ni Coating

In another embodiment, WC-5 wt. % Ni coatings were deposited onto mild steel using a low pressure cold spray machine. Samples were ground and polished to a 1 μm surface finish, and then ultrasonically cleaned prior to implantation. An Nb ion dosage of 1×10¹⁷ ions cm⁻² at an acceleration voltage of 170 keV was selected.

The coating samples, both ion implanted and un-implanted, were characterized using an AFM (Dimension 3100, Digital Instruments Inc., USA) coupled with Nano Scope Analysis Version 1.30 (Bruker Corporation, USA) to measure the surface roughness. Micro-Vickers hardness was done on the planar surfaces using a 0.49 N load, with a 10 second dwell time, according to ASTM1327. In this embodiment, the hardness of the un-implanted and the Nb⁺ implanted WC-5 wt. % Ni coatings were found to be 4.32±0.15 GPa and 6.25±0.39 GPa respectively. The lower hardness values obtained, compared to those detailed previously, is attributed to the fact that the cold spray deposition was onto mild steel substrates, rather than stainless steel.

### EXAMPLE 6

### Preparation of a Cold Sprayed Ru Implanted WC-5 wt % Ni Coating

WC-5 wt % Ni cermet coatings were deposited onto 3CR12 stainless steel plates (20 mm×20 mm×3 mm) using a low pressure cold gas dynamic spray machine (Centerline SST Series P, Canada).

Coating samples were ground using standard metallographic procedures and polished to a 1 μm surface finish, and then ultrasonically cleaned prior to the ion implantation process. The selected Ru ion sputtering target (Ruthenium (99.9%, Goodfellow, UK) was implanted into the cermet coatings at a dosage of 8×10¹⁶ ions cm⁻² at an acceleration voltage of 60 keV (200-20A2F ion implanter, iThemba LABS, South Africa).

Micro-Vickers hardness of the coating sample was done on the planar surface using a 0.49 N load, with a 10 second dwell time, according to ASTM1327. In this embodiment, the hardness of the Ru⁺ implanted WC-5 wt. % Ni coating increased to 13.21±0.81 GPa which translates into an increase of about 18% compared to the un-implanted WCNI coating.

This above description of some of the illustrative embodiments of the invention is to indicate how the invention can be made and carried out. Those of ordinary skill in the art will know that various details may be modified thereby arriving at further embodiments, but that many of these embodiments will remain within the scope of the invention.

1. An ion implanted cold sprayed hardmetal cemented carbide coating, the coating comprising a hardmetal carbide and a binder metal M selected from the group consisting of nickel, cobalt, copper, iron, and alloys thereof, wherein the coating is implanted with ions selected from the group consisting of Nb⁺, Mo⁺, W⁺, Ta⁺, and Ru⁺.

2. The ion implanted cold sprayed coating according to claim 1, wherein the hardmetal cemented carbide is selected from the group consisting of WC-M, TiC-M, TaC-M, ZrC-M, Cr2C3-M, NbC-M, VC-M, and MoC-M, or mixtures thereof.

3. The ion implanted cold sprayed coating according to claim 1, wherein the binder metal M is present at a concentration of about 2% to about 20% by weight of the total coating.

4. The ion implanted cold sprayed coating according to claim 3, wherein the binder metal M is present at a concentration of about 3% to about 15% by weight of the total coating.

5. The ion implanted cold sprayed coating according to claim 3, wherein the binder metal M is present at a concentration of about 5% to about 10% by weight of the total coating.

6. The ion implanted cold sprayed coating according to claim 1, wherein the coating is implanted with Nb⁺ ions.

7. The ion implanted cold sprayed coating according to claim 1, wherein the binder metal M is selected from the group consisting of nickel, cobalt, iron, and alloys thereof.

8. The ion implanted cold sprayed coating according to claim 7, wherein the binder metal M is selected from nickel and alloys thereof.

9. The ion implanted cold sprayed coating according to claim 1, wherein the ions are implanted at a dosage in the range of about 1×10¹⁶ to about 1×10¹⁷ ions cm⁻².

10. The ion implanted cold sprayed coating according to claim 9, wherein the ions are implanted at a dosage of about 2×10¹⁶, about 5×10¹⁶, about 8×10¹⁶, or about 1×10¹⁷ ions cm⁻².

11. A method of forming an ion implanted cold sprayed hardmetal cemented carbide coating, the method comprising the steps of:
(a) cold spraying a hardmetal cemented carbide coating onto a substrate to be coated, and
(b) implanting ions selected from the group consisting of Nb⁺, Mo⁺, W⁺, Ta⁺, and Ru⁺ with an ion implanter at an acceleration voltage of about 40 keV to about 170 keV,
wherein the coating comprises a hardmetal carbide and a binder metal M selected from the group consisting of nickel, cobalt, copper, iron, and alloys thereof.

12. The method according to claim 11, wherein the hardmetal cemented carbide is selected from the group consisting of WC-M, TiC-M, TaC-M, ZrC-M, Cr2C3-M, NbC-M, VC-M, and MoC-M, or mixtures thereof.

13. The method according to claim 11, wherein the binder metal M is present at a concentration of about 2% to about 20% by weight of the total coating.

14. The method according to claim 13, wherein the binder metal M is present at a concentration of about 3% to about 15% by weight of the total coating.

15. The method according to claim 13, wherein the binder metal is present at a concentration of about 5% to about 10% by weight of the total coating.

16. The method according to claim 11, wherein the coating is implanted with Nb⁺ ions.

17. The method according to claim 11, wherein the binder metal M is selected from the group consisting of nickel, cobalt, iron, and alloys thereof.

18. The method according to claim 17, wherein the binder metal M is selected from nickel and alloys thereof.

19. The method according to claim 11, wherein the ions are implanted at a dosage in the range of about 1×10¹⁶ to about 1×10¹⁷ ions cm⁻².

20. The method according to claim 19, wherein the ions are implanted at a dosage of about 2×10¹⁶, about 5×10¹⁶, about 8×10¹⁶, or about 1×10¹⁷ ions cm⁻².

21-22. (canceled)
